(19) United States
(12) Patent Application Publication
(10) Pub. No.: US 2008/0305634 A1
(43) Pub. Date: Dec. 11, 2008

(54) Metal Film Separation Prevention Structure in Metal Film Forming Device, and Semiconductor Device Manufacturing Method Using Said Structure

(75) Inventor: Toshifumi Igarashi, Ibaraki (JP)

Correspondence Address: TEXAS INSTRUMENTS INCORPORATED, P O BOX 655474, M/S 3999, DALLAS, TX, 75265, US

(73) Assignee: TEXAS INSTRUMENTS INCORPORATED, Dallas, TX (US)

(21) Appl. No.: 12/122,794

(22) Filed: May 19, 2008

(30) Foreign Application Priority Data
May 23, 2007 (JP) 2007-136863

(51) Int. Cl. H01L 21/44; B05C 11/00

(52) U.S. Cl. 438/688; 118/45; 257/E21.476

(57) ABSTRACT

The object of this invention is to prevent unwanted separation of a deposited metal film from a member, such as an anti-adhesion plate, in the chamber of a metal film forming device. In a sputtering device, metal particles sputtered from the surface of a target 12 in a chamber 10 are not only dispersed or scattered toward a semiconductor wafer 22 on the front of the target, but also adhere to shield member 30 to form a deposited metal film 40. Shield member 30 is made of stainless steel, for example, a plasma spray film made of aluminum or an aluminum alloy is formed on its anti-adhesion surface (inner wall surface), and the surface of the plasma spray film is suitably roughened.

### FIELD OF THE INVENTION

The present invention pertains to technology to prevent particle contamination of processed substrates in the vacuum chambers of metal film forming devices, and in particular relates to a metal film separation prevention structure that prevents or curbs undesired separation of a metal film deposited and adhered to a member in the chamber and a semiconductor device manufacturing method using said structure.

### BACKGROUND OF THE INVENTION

In the manufacture of semiconductor devices, in order to form metal wiring on the principal face (worked face) of the processed substrate, e.g., a semiconductor wafer, metal wiring is formed on the substrate in the processing chamber or vacuum chamber of a metal film forming device. Current representative metal film forming methods are sputtering and CVD (chemical vapor deposition). However, with these vapor phase film forming methods, metal particles unavoidably caused by film formation in the vacuum chamber are generated, some of which have a possibility of adhering to the substrate. The adhesion of such particles to the substrate is a significant factor in lowering the yield of semiconductor device manufacturing and the working rate of the manufacturing device.

In sputtering devices, a so-called shield member—a round tubular anti-adhesion plate—is detachably disposed on the inside of the chamber inner walls to enclose the space connecting the target and substrate (processing space) to prevent dispersion of particles sputtered from the target. Sputtered particles of metal dispersed or scattered around the substrate during sputter film formation adhere to the shield member and are deposited there, so the chamber inner walls positioned behind the shield member are protected from metal adhesion or deposition, and special cleaning is unnecessary. An old shield member is periodically replaced with a new one, and the old shield member removed from the chamber is reused as a recycled component after removing the deposited metal film and cleaning the surface.

However, if the deposited metal film separates during the period in which the shield material is being used (mounted) in the chamber, it becomes a source of dust or a source of particle generation. Particularly if the metal is Ti, TiN or another refractory metal, the stress on the deposited metal film is very great, so adhesion of the metal film is lower merely because the surface of the base material (stainless steel, for example) is roughened by plasma treatment, and the metal film readily separates. For this reason, conventionally the shield member replacement cycle is necessarily shortened from the standpoint of preventing the occurrence of such particles as described above, causing a lowered device working rate, increased shield member recycling expense, etc.

### SUMMARY

The present invention was devised in consideration of the circumstances described above, with the objective of providing a metal film separation prevention structure that can simply and effectively prevent unwanted separation of a deposited metal film from a member, such as an anti-adhesion plate, in the chamber of a metal film forming device, and a semiconductor device manufacturing method using said structure.

To accomplish the aforementioned objective, the metal film separation prevention structure of the present invention is a metal film separation prevention structure in a metal film forming device wherein a metal thin-film is formed on a processed substrate in a chamber at reduced pressure, wherein in order to prevent separation of the aforementioned deposited metal film from a specified member on which the aforementioned metal is deposited by adhesion around the aforementioned substrate when a metal film is formed in the aforementioned chamber, a plasma spray film made of aluminum or an aluminum alloy is formed on the surface of the aforementioned member and the surface of the aforementioned plasma spray film is roughened.

In the constitution above, by forming a plasma spray film made of aluminum or an aluminum alloy with outstanding stress moderating capability on the surface of a member (an anti-adhesion plate, for example) on which the metal of the film forming material is unavoidably adhered or deposited in the chamber of a metal film forming device (a sputtering device, for example) and suitably roughening the surface thereof, adhesion between the deposited metal film and the plasma spray film increases, separation of the metal film is curbed, and particle contamination of the processed substrate caused by film separation is prevented or reduced.

The surface roughness of the plasma spray film may ideally be selected in the range 65 μm≦Rz≦130 μm, as the ten-point height of irregularities Rz. By selecting in the range of 100 μm≦Rz≦130 μm in particular, prevention of separation of the deposited metal film can be ensured stably and reliably over a long period of use.

For ensuring adhesion or bonding strength between the deposited metal film and the plasma spray film, the spacing of the convexities and concavities in the surface of the plasma spray film is also important, and the mean spacing is preferably selected in the range of 200 μm-400 μm.

To moderate stress in the deposited metal film, particularly when the metal material is a refractory metal or refractory metal nitride, the thickness requirements for the plasma spray film are also important, and the mean film thickness is preferably selected to be 200 μm or more.

The semiconductor device manufacturing method in the present invention is a semiconductor device manufacturing method that includes a process to apply metal film forming processing to a semiconductor wafer in a chamber provided with a metal film anti-adhesion member, and has a process to introduce a semiconductor wafer into the chamber, a process to apply metal film formation processing to the aforementioned semiconductor wafer, a process to remove the metal film anti-adhesion member in the chamber, a process to clean the removed anti-adhesion member, a process to install the cleaned anti-adhesion member in the aforementioned chamber, a process to introduce a semiconductor wafer into the chamber, and a process to apply metal film formation processing to the aforementioned semiconductor wafer, and wherein a plasma spray film made of aluminum or an aluminum alloy is formed on the surface of the aforementioned anti-adhesion member, and the roughness of the surface of the aforementioned plasma spray film is in the range 65 μm≦Rz≦130 μm, as the ten-point height of irregularities Rz.

### BRIEF DESCRIPTION OF THE DRAWINGS

FIG. 1 is a longitudinal cross section showing the constitution of a sputtering device in an embodiment of the present invention.

FIG. 2 is a partial enlarged cross section showing the sectional structure of the shield member surface portion in region A in FIG. 1.

FIG. 3A is a schematic view for explaining the action of the present invention at the surface of the plasma spray film.

FIG. 3B is a schematic view for explaining the action of a comparative example at the surface of the plasma spray film.

FIG. 4 is a figure showing an example of the surface roughness curve of a plasma spray film formed on the surface of a shield member in an embodiment of the present invention.

FIG. 5 is a graph showing the relationship between the thickness of the plasma spray film formed on the surface of the shield member and its stress moderating capability in an embodiment of the present invention.

FIG. 6 is a flowchart showing the production or recycling method procedure for a metal film separation prevention structure pertaining to an anti-adhesion plate in an embodiment of the present invention.

FIG. 7 is a partial enlarged cross section showing the constitution of the major parts of the metal film separation prevention structure in an embodiment of the present invention.

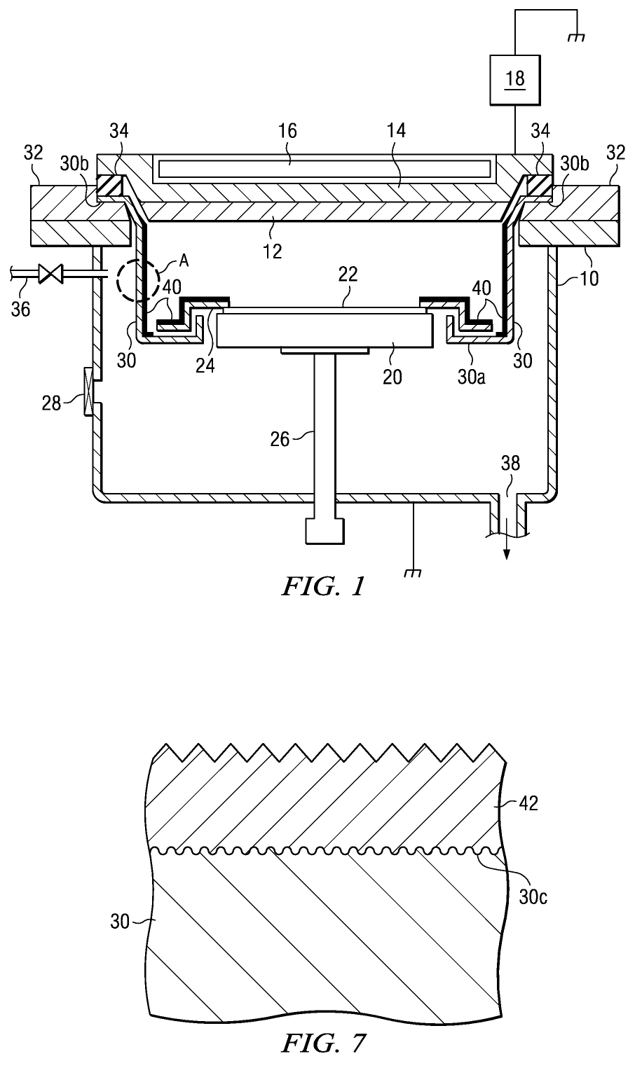

### REFERENCE NUMERALS AND SYMBOLS AS SHOWN IN THE DRAWINGS

In the figures, 10 represents a chamber, 12 represents a target, 14 represents a backing plate, 16 represents a magnet, 18 represents a power source, 20 represents a stage, 22 represents a semiconductor wafer (processed substrate), 30 represents a shield member (anti-adhesion plate), 40 represents a deposited metal film, 42 represents a plasma spray film.

### DESCRIPTION OF THE EMBODIMENTS

With the metal separation prevention structure and the semiconductor device manufacturing method using said structure of the present invention, unwanted separation of a deposited metal film from a member, such as an anti-adhesion plate, in the chamber of a metal film forming device can be simply and effectively prevented using the constitution and action as described above.

Below, an ideal embodiment of the present invention will be explained referring to the accompanying figures. The constitution of a sputtering device as an example of a metal film forming device that is applicable to the present invention is shown.

In this sputtering device, chamber 10 is formed in a closed-bottom cylindrical form made of stainless steel, etc., and a backing plate (electrode) 14 to which target 12 is affixed on the underside is detachably attached to hermetically close the opening in the top face of chamber 10. On the back (top surface) of backing plate 14, a magnet 16 is furnished to apply a magnetic field to the surface of target 12, so that so-called magnetron sputtering will be performed. An RF or DC power source 18 to form an electrical field is electrically connected to backing plate 14.

Inside chamber 10, a stage 20 made of a conductor is furnished in a position directly opposite target 12, and the processed substrate, for example, a semiconductor wafer 22, is mounted on stage 20. A ring-shaped clamp member (clamp ring) 24 is fastened to the outside edge of wafer 22 to affix semiconductor wafer 22 to stage 20.

Stage 20 is supported on a support shaft 26 that can move up and down to extend vertically through the bottom plate of the chamber from below (outside) chamber 10, and electrically it is also grounded to chamber 10. Support shaft 26 is connected to an elevating mechanism (not shown) below (outside) chamber 10 and can move stage 20 up and down between a first height position for film forming where semiconductor wafer 22 is fastened in clamp ring 24 as shown and a second height position for substrate loading and unloading to enable semiconductor wafer 22 on stage 20 to be loaded or unloaded with a gate valve 28 mounted in the side wall of chamber 10 opened. Here, chamber 10 is constituted to be able to be depressurized, and the through-hole through which support shaft 26 can slide is vacuum sealed with a sealing member (not shown).

Inside chamber 10, a cylindrical shield member 30 smaller in diameter than chamber 10 is disposed to enclose the space (processing space) connecting target 12 and semiconductor wafer 22 with semiconductor wafer 22 on stage 20 raised to the height position at clamp ring 24 (first height position for film forming).

The lower end of shield member 30 constitutes a ring-shaped flange part 30a that extends inward in the radial orientation, and clamp ring 24 is mounted on inside flange part 30a. The upper end of shield member 30 constitutes a ring-shaped flange part 30b that extends outward in the radial orientation, and shield member 30 is detachably mounted via an adaptor 32 in chamber 10 so that outside flange part 30b lies above the opening in the top face of chamber 10. Backing plate 14 and target 12 are detachably attached to the top face of chamber 10 so that the peripheral edge of backing plate 14 will lie on outside flange part (30b) of shield member 30 via an insulating o-ring 34.

During sputter film formation, an inert gas, Ar gas, for example, is introduced into chamber 10 through a gas feed pipe 36 from a gas feed source (not shown). Exhaust opening 38 furnished at the bottom of chamber 10 goes to a vacuum pump (not shown), and the inside of chamber 10 is depressurized to a high vacuum with a specified pressure. Then by impressing voltage between target 12 and stage 20 from power source 18, Ar gas is ionized in the processing space, plasma is generated, the surface of target 12 is sputtered by the incidence of accelerated Ar ions from the target, and the sputtered particles are deposited on the principal face of semiconductor wafer 22 on stage 20 to form a metal thin-film.

When a refractory metal film, for example, Ti nitride, TiN, is formed, the material for target 12 is Ti, and nitrogen (N₂) gas is added to the Ar gas as the process gas, and so-called reactive sputtering may be performed. That is, the sputtered Ti particles sputtered by the Ar ions and the nitrogen ions react, and a TiN nitride film can be formed on the principal face of semiconductor wafer 22.

In sputter film formation as described above, the metal particles sputtered from the surface of target 12 are dispersed or scattered not only toward semiconductor wafer 22 facing the target, but also adhere particularly to the inner wall surfaces (anti-adhesion surfaces) of shield member 30, the top surface of clamp ring 24, etc., forming a deposited metal film 40.

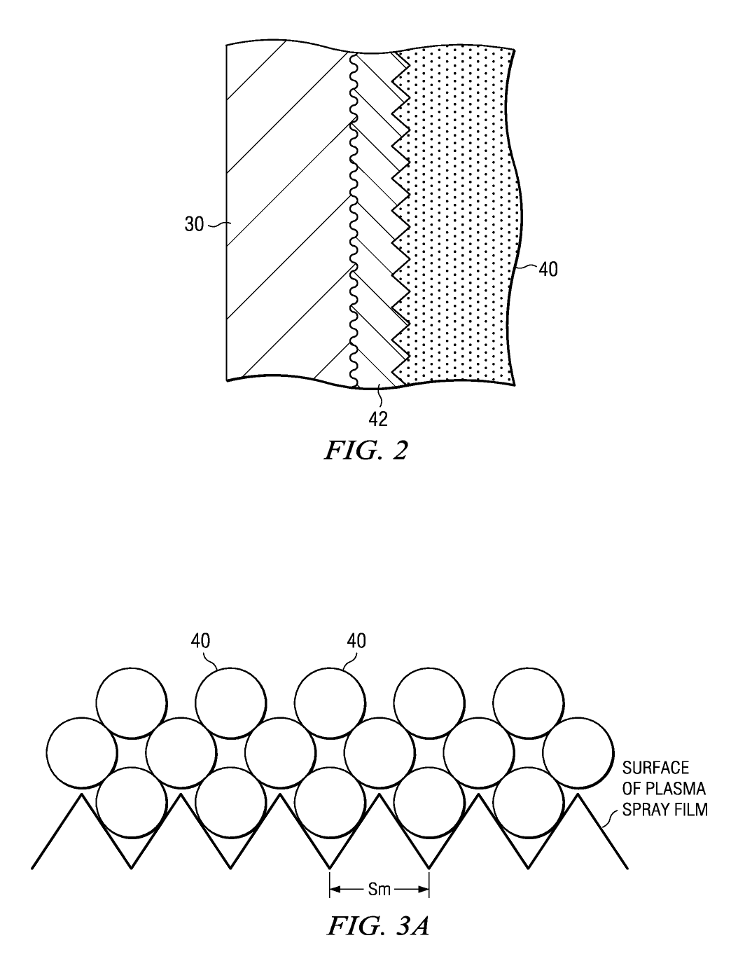

Shield member 30 in this embodiment is made of stainless steel, for example, and as shown in FIG. 2, on the anti-adhesion surface thereof (inner wall surface), a plasma spray film 42 made of aluminum (Al), or an aluminum alloy containing a metal such as copper (Cu), magnesium (Mg) or zinc (Zn) is formed, and the surface of plasma spray film 42 is suitably roughened.

Here, when the surface roughness of plasma spray film 42 is represented by the ten-point height of irregularities Rz, the lower limit preferably satisfies the requirement 65 μm≦Rz, and more preferably satisfies the requirement 100 μm≦Rz. If Rz is less than 65 μm, the adhesion (bonding strength) with deposited metal film 40 is weak, as will be described in detail below, and the effect of preventing or curbing film separation is not sufficiently obtained. If Rz is 100 μm or more, sufficient adhesion (bonding strength) is obtained with deposited metal film 40, and film separation can be stably and reliably prevented even if deposited metal film 40 is 1 mm or more thick. It is also preferable that the upper limit of Rz satisfy the requirement Rz≦130 μm. Even if Rz exceeds 130 μm, the film separation prevention effect is satiated and will not increase, and in addition, the limit on maximum thickness that is possible with plasma spraying is exceeded, so it is meaningless in practical terms. As for the surface roughness of plasma spray film 42, not only the height of the concavities and convexities, but the pitch or spacing of the concavities and convexities is also important in the relationship with adhesion of deposited metal film 40, and it is preferable that mean spacing (Sm) be in a specified range (200 μm-400 μm) as described below.

In addition, to increase the bonding strength between shield member 30 and plasma spray film 42, it is preferable that the surface of shield member 30 be roughened to a suitable roughness (preferably in the range 4.5≦Ra≦7 μm, with center line mean roughness Ra) using a plasma treatment.

With this embodiment as described above, by application of a plasma spray film 42, the surface of which has been suitably roughened, to shield member 30 furnished as an anti-adhesion plate in chamber 10 of a sputtering device, even if metal sputter film formation processing is performed multiple times and a metal film is deposited on shield member 30, even if the metal is a refractory metal (Ti, for example) or a nitride thereof (TiN) with large stress, separation of deposited metal film 40 is prevented or curbed, and particle contamination of the processed substrate (semiconductor wafer 22) in chamber 10 decreases. The implementation of periodic cleaning of the inside of chamber 10 or the replacement (cycling) of shield member 30 can be delayed to the extent that separation of deposited metal film 40 from shield member 30 becomes difficult, and an improved device working rate, reduced shield member recycling expense, and lower cost in the manufacturing process are also achieved.

In the sputtering device in this embodiment, when metal sputter film formation processing is repeated, deposited metal film 40 is also formed on the surface of clamp ring 24, for example, as well as on shield member 30. Therefore, a plasma spray film may also be formed on clamp ring 24 in the same way as aforementioned plasma spray film 40, and the same functional effects can be obtained with it.

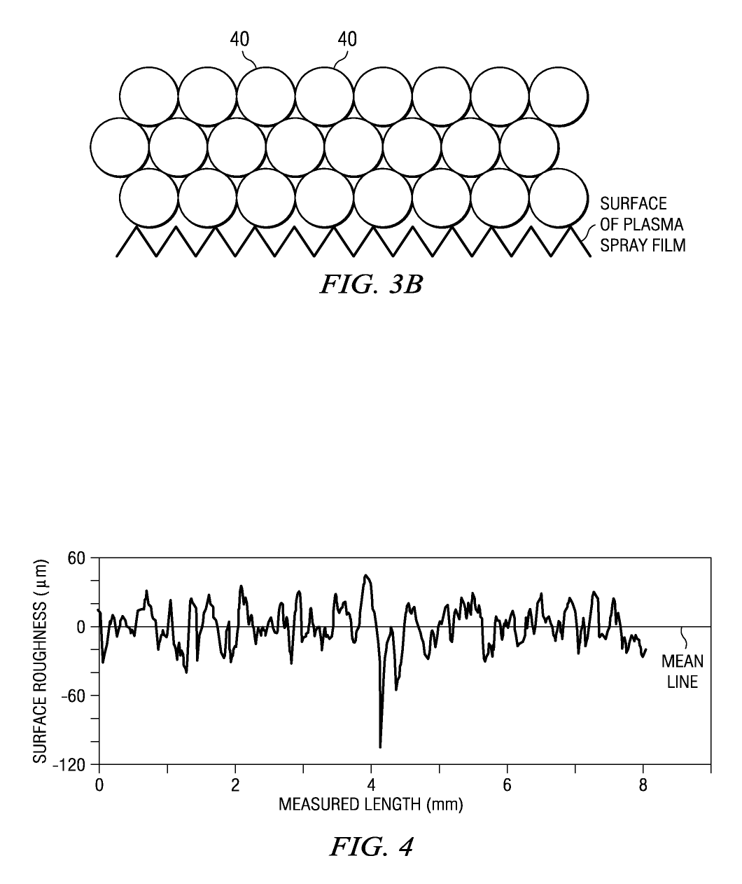

Here, the action of the surface roughness of the plasma spray film in this embodiment will be explained referring to the schematic view in FIG. 3. FIG. 3A is a case wherein the surface roughness of the plasma spray film is Rz=100 μm in accordance with the present invention. In this case, sputtered particles 40 of metal coalesce into the white circles in the figure, for example, and adhere so that the lowermost portion of the film is embedded in the concave and convex parts, and the deposited film is grown in the form of a pillar. Because the adhesion surface area between deposited metal film 40 and the concave and convex parts of the plasma spray film surface is large in this way, the adhesive strength (bonding strength) between the two is large.

In contrast to this, FIG. 3B is a case wherein the surface roughness of the plasma spray film is Rz=50 μm. Conventional ordinary plasma spraying produces a surface roughness that is that fine. In that case, deposited metal film 40 is adhered in a form lying on the convex parts without entering the concave and convex parts of the plasma spray film surface, and the deposited film is grown in the form of a pillar. For this reason, the contact surface area is small, the degree of adhesion is not good, and the film readily separates from the boundary.

As for the surface roughness of plasma spray film 42, not only the height of the concavities and convexities, but the spacing between concavities and convexities is important. That is, because with sputter film formation, the flight of sputtered particles is curbed in a shadow zone that can occur between the concave parts or the convex parts of the uneven surface part of plasma spray film 42, sufficient growth of metal film 40 will not occur in that region, and the adhesive strength thereof drops. Such a shadow effect in sputter film formation is also associated with a difference in height between the convex parts and the concave parts of the uneven surface part and depends on the mean spacing (Sm) of concavities and convexities, which preferably is usually selected in the range of 200 μm≦Sm≦400 μm.

An example of a surface roughness curve for plasma spray film 42 in this embodiment is shown in FIG. 4. The surface roughness curve was measured using a HANDY SUFE-35A surface roughness meter made by Tokyo Seimitsu (Ltd.). In this surface roughness curve, the ten-point height of irregularities Rz is 114.5 μm, and the mean spacing (Sm) of surface concavities and convexities is around 300 μm.

Here, as for the plasma spray method, argon is converted to plasma as the working gas, the spray material is thrown into a plasma jet that is sprayed at high temperature and high speed from a nozzle toward a substrate (sprayed body), and it is heated and accelerated and blown against the substrate. In this embodiment, design was concentrated on aluminum powder, which is a spray material powder, to obtain the surface roughness curve in FIG. 4.

In the case of metal film formation, particularly in the case of a refractory metal or a nitride thereof, because the film stress in deposited metal film 40 formed on plasma spray film 42 is extremely large, the thickness of plasma spray film 42 is also an important factor for the film separation prevention function to moderate or absorb film stress in deposited metal film 40.

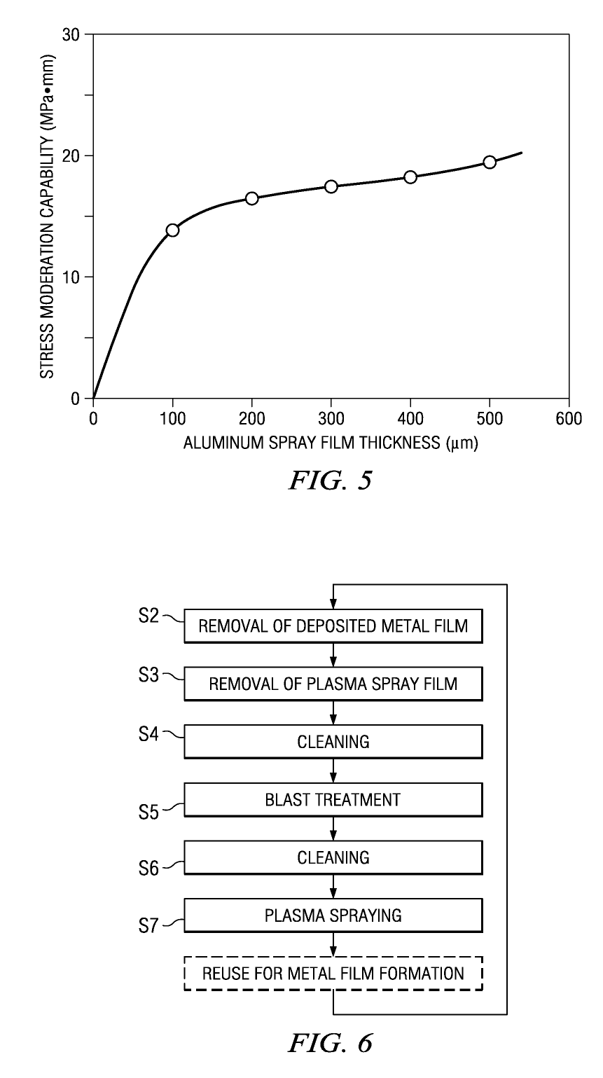

The relationship between the thickness of a plasma spray film made of aluminum (aluminum spray film thickness) and the stress moderation capability thereof is shown in FIG. 5. Here, the stress moderation capability is a value wherein the film stress in a metal film (TiN film, for example, in the figure) when the plasma spray film starts to separate from the shield member is represented in surface tension units.

As shown in FIG. 5, the fact that the stress moderation capability for the deposited metal film increases as the aluminum spray film thickness increases, and the fact that the stress moderation capability is essentially satiated at a film thickness of 200 μm or more can be seen. From these facts, it is preferable that the film thickness be 200 μm or more in plasma spray film 42 in this embodiment as well.

When a shield member 30 in this embodiment was used for Ti film formation processing for a semiconductor wafer of 200 mm diameter under conditions wherein the thickness of shield member 30 was 1.3 mm and the thickness of the plasma spray film (Al) was 300 μm, at the stage where Ti deposited film 40 had been grown to a thickness of about 1 mm on shield member 30 with an estimated usage time of 500 kWh, absolutely no separation of Ti deposited film 40 was seen.

Next, the production or recycling method for the metal film separation prevention structure pertaining to the anti-adhesion plate (shield member 30, for example) in this embodiment will be explained by referring to FIG. 6 and FIG. 7.

To implement periodic cleaning of the inside of chamber 10, old shield member 30 that has been used up to then is removed for replacement by a new one. In the flowchart in FIG. 6, target 12 is removed as a unit with backing plate 14 from the top face of chamber 10, and shield member 30 and clamp ring 24 are also removed outside chamber 10. For shield member 30, deposited metal film 40 remaining on its anti-adhesion surface is removed (step S₂). A chemical agent solution is used to selectively etch metal film 40 in the processing to remove the metal film.

Next, Al metal plasma spray film 42 is etched off using a chemical agent solution, for example (step S₃).

Next, the surface of shield member 30 is cleaned by ultrasonic cleaning in pure water or by immersion cleaning in a chemical agent solution, for example (step S₄).

Next, the anti-adhesion surface of shield member 30 is blast treated (step S₅). The particles used for blast treatment may be sand, quartz, alumina or other microparticles, and it is preferable that the grain size be in the range of #40-#100. The surface of the base material of shield member 30 is roughened 30c to within a suitable range (4.5 μm≦Ra≦7 μm) as shown schematically in FIG. 7 by this blast treatment. The adhesive strength of plasma spray film 42 formed in a later process on top of it can be increased by roughening the base material of shield member 30. Here, it is preferable that the microparticles used for blast treatment be graded using a screen, for example, so that the particle diameters will be uniform. The grain size # corresponds approximately to the number of microparticles that can be arranged in 10 mm².

After this, the surface of the base material of shield member 30 that has been roughened using blast treatment is cleaned (step S₆). In the cleaning process, a cleaning method, such as ultrasonic cleaning or chemical reagent cleaning, may be used such that particles adhered to the surface of the base material surface of shield member 30 can be efficiently removed.

Finally, as shown in FIG. 7, metal Al, for example, is plasma sprayed on rough surface (30c) of shield member 30 to form plasma spray film 42 (step S₇), and the surface of plasma spray film 42 at this time is roughened according to the aforementioned specified conditions (Rz, Sm).

Shield member 30 is recycled as above. Then a recycled shield member 30 is then periodically mounted in chamber 10 of the sputtering device and is reused. Recycling as described above can also be performed for clamp ring 24.

The action and effects of the roughened uneven surface of plasma spray film 42 explained in the abovementioned embodiment are not limited to application to shield member 30, and the same action and effects as described above can be obtained by furnishing the same type of roughened uneven surface for any members used in the chamber of a sputtering device. Surface treatment using the same type of plasma spray as described above could also be applied to any members used in a collimation sputtering device provided with a collimator, as well as an MOCVD (metal organic chemical vapor deposition) device, ALD (atomic layer deposition) device or any other type of metal film forming device.

While an ideal embodiment of the present invention was explained above, the abovementioned embodiment does not limit the present invention. Various modifications and changes that do not deviate from the technical concept and technical scope of the present invention can be added to actual embodiments by persons skilled in the art.

1. A metal film separation prevention structure in a metal film forming device with which a metal thin-film is formed on a treated substrate in a chamber at reduced pressure,
which is a metal film forming device wherein, in order to prevent or curb separation of the deposited metal film from a specified member where the aforementioned metal is deposited by adhering around the aforementioned substrate when a metal film is formed against the aforementioned substrate in the aforementioned chamber, a plasma spray film made of aluminum or an aluminum alloy is formed on the surface of the aforementioned member, and the surface of the aforementioned plasma spray film is roughened.

2. The metal film separation prevention structure described in claim 1 wherein the surface roughness of the aforementioned plasma spray film is in the range of 65 μm≦Rz≦130 μm, as the ten-point height of irregularities Rz.

3. The metal film separation prevention structure described in claim 2 wherein the surface roughness of the aforementioned plasma spray film is in the range of 100 μm≦Rz≦130 μm, as the ten-point height of irregularities Rz.

4. The metal film separation prevention structure described in claim 1 wherein the mean spacing of concavities and convexities in the surface of the aforementioned plasma spray film is in the range of 200 μm-400 μm.

5. The metal film separation prevention structure described in claim 1 wherein the mean thickness of the aforementioned plasma spray film is 200 μm or more.

6. The metal film separation prevention structure described in claim 1 wherein the aforementioned metal is a refractory metal or a nitride of a refractory metal.

7. The metal film separation prevention structure described in claim 1 wherein the aforementioned member includes an anti-adhesion plate to prevent adherence of a deposited film of the aforementioned metal to the inner walls of the aforementioned chamber.

8. The metal film separation prevention structure described in claim 1 wherein the aforementioned metal film forming device is a sputtering device that forms a metal thin-film on the aforementioned substrate with sputtering.

9. A semiconductor device manufacturing method that includes a process to apply metal film formation processing to a semiconductor wafer in a chamber provided with a metal film anti-adhesion member,
which is a semiconductor device manufacturing method having:
a process wherein a semiconductor wafer is introduced into a chamber,
a process to apply metal film formation processing to the aforementioned semiconductor wafer,
a process to remove the metal film anti-adhesion member in the chamber,
a process to wash the removed anti-adhesion member,
a process to install the washed anti-adhesion member in the aforementioned chamber,
a process to introduce a semiconductor wafer into a chamber,
and a process to apply metal film formation processing to the aforementioned semiconductor wafer,
and wherein a plasma spray film made of aluminum or an aluminum alloy is formed on the surface of the aforementioned anti-adhesion member, and the surface roughness of the aforementioned plasma spray film is in the range 65 μm≦Rz≦130 μm, as the ten-point height of irregularities Rz.
